(19) United States
(12) Patent Application Publication
(10) Pub. No.: US 2005/0168218 A1
(43) Pub. Date: Aug. 4, 2005

(54) Magnetic sensor system

(75) Inventor: Torsten Wedemeyer, Porta Westfalica (DE)

Correspondence Address: BARNES & THORNBURG, 750-17TH STREET NW, SUITE 900, WASHINGTON, DC, 20006, US

(73) Assignee: Bernstein AG

(21) Appl. No.: 10/953,574

(22) Filed: Sep. 30, 2004

(30) Foreign Application Priority Data
Oct. 8, 2003 (DE) 203 15 448.7

(51) Int. Cl. G01B 7/14; G01B 7/30; G01R 33/06

(52) U.S. Cl. 324/207.26; 324/207.2

(57) ABSTRACT

A magnetic sensor system, particularly for transport systems, including a ferromagnetic generator which can be moved relative to a magnetic sensor. The magnetic sensor is arranged in the magnetic fields of at least two adjacent magnets in whose magnetic field the generator can be moved. The magnetic fields are constructed as two overlapping lobes, whereby the positioning of the generator can be detected particularly well.

### BACKGROUND AND SUMMARY OF THE DISCLOSURE

The present invention relates to a magnetic sensor system, particularly for transport systems, having a ferromagnetic generator, which can be moved relative to a magnetic sensor.

There are sensors which use inductive operating principle to detect electrically conductive materials. As a result of their large adjustable sensitivity, usually large working air gaps can be implemented. However, inductive sensors have the disadvantage that they may be influenced by non-ferromagnetic metallic system parts, such as aluminum. Since, as a result of the arrangement of the signal or ferromagnetic generator, such a sensor should have a wide sensitive track transversely to the moving direction, this leads to a relatively large design. In the case of inductive sensors, the maximal switching frequency depends on the size of the sensor. The minimal demands on the switching frequency are not achieved by an inductive solution.

Additional, commercially available proximity switches are equipped with a comparator circuit which compares an absolute desired value with an absolute actual value. These proximity switches have the disadvantage that the sensitivity of the sensor and the pulse duty ratio are dependent on the temperature. In addition, the sensors have to be calibrated.

It is therefore an object of the present system to create a magnetic sensor system which has a considerable sensitivity and a simple construction while its size is small.

The present magnetic sensor system includes a magnetic sensor arranged in the magnetic fields of at least two adjacent magnets in whose magnetic field the ferromagnetic generator can be moved. As a result of the arrangement of the sensor in the static magnetic field, when the generator is moved into the magnetic field, a signal is generated starting at a predefined threshold value, by means of which signal the positioning of the generator is detected. The homogeneous magnetic field is disturbed by the approaching of the ferromagnetic generator. The deflection of the homogenous field lines generates an analyzable signal amplitude. In this case, it is not important which of the at least two magnetic fields is influenced by the generator. The resulting signal amplitude is independent of the overlapping between the sensor and the generator as long as this signal amplitude is detected.

For a sensor system of a particularly simple construction, the magnetic fields are shaped as two overlapping lobes. As a result of the lobes, a comparatively large range is obtained relative to the size of the sensor system.

The sensor is preferably constructed as a Hall sensor. The Hall sensor is an analog element, wherein the output voltage is proportional to the magnetic flux density. Such a Hall sensor is particularly suitable for a use with semiconductor switches.

For a compact construction, two magnets are provided between which the sensor is arranged in the center in the area of parallel field lines. More than two magnets, for example, four magnets, may also be provided. It is also conceivable that a plurality of magnets surrounds the sensor in a ring-shaped manner; for example, when the approaching of the generator can take place not only from two directions but from several directions.

Preferably, a temperature measuring device is provided for temperature compensation of the detection where the sensor is essentially dependent on the temperature. The reason is that sensors, particularly Hall sensors, are temperature-dependent per se and the magnetic flux density of the magnets decreases as the temperature increases, which is why a compensation is necessary. By a corresponding temperature compensation, the temperature influences on the sensor system can be minimized.

The switching frequency of the sensor is preferably above 5 kHz, particularly above 10 kHz. Such a high switching frequency is not reached by most inductive solutions.

The working air gap between the sensor and the generator is preferably in a range of between 1 and 14 mm, so that a sufficient temperature compensation can take place by the sensor system.

The sensor system can additionally comprise a microcontroller-controlled electronic analyzing system, by which the sensor system can also be constructed to be adaptive to a certain degree.

These and other aspects of the present disclosure will become apparent from the following detailed description of the disclosure, when considered in conjunction with accompanying drawings.

### BRIEF DESCRIPTION OF THE DRAWINGS

FIG. 1 is a perspective view of a sensor system according to the present disclosure.

FIG. 2 is a schematic top view of the sensor system of FIG. 1.

FIG. 3 is a representation of the magnetic field of the sensor system of FIG. 1 without the generator.

FIG. 4 is a representation of the magnetic field of the sensor system of the figure with the generator.

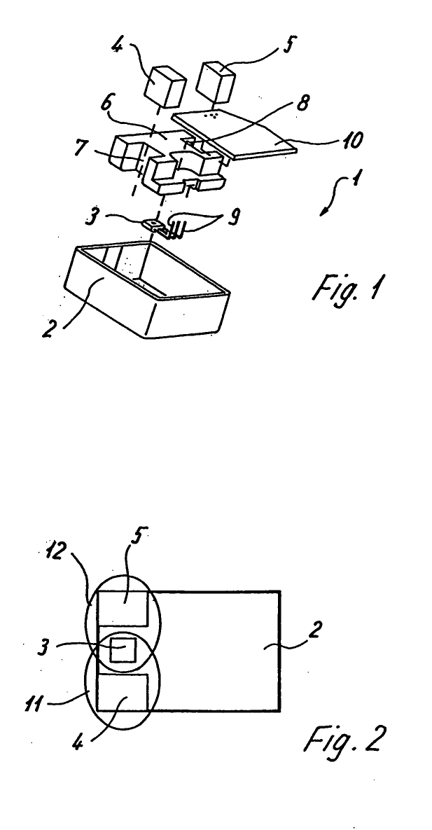

### DETAILED DESCRIPTION OF THE PREFERRED EMBODIMENTS

A sensor system 1 comprises a housing 2, in which a sensor 3 (for example, a Hall sensor) can be mounted. A first magnet 4 and a second magnet 5 are accommodated in the housing 2. The Hall sensor 3 and the magnets 4 and 5 are fixed by a body 6 which has a recess 7 for the magnet 4 and a recess 8 for the magnet 5 as well as a recess on the bottom side for the Hall sensor 3. In this case, the Hall sensor is connected by leads 9 with a printed circuit board 10 on which an electronic analyzing system can be arranged.

As illustrated in FIG. 2, the Hall sensor 3 is situated between the magnets 4 and 5. In this case, magnet 4 generates a lobar magnetic field 11 which includes the Hall sensor 3. In a similar manner, magnet 5 generates a lobar magnetic field 12 which also includes the Hall sensor 3. In the illustrated sensor system, the magnets 4 and 5 or the magnetic fields 11 and 12 have a symmetrical construction.

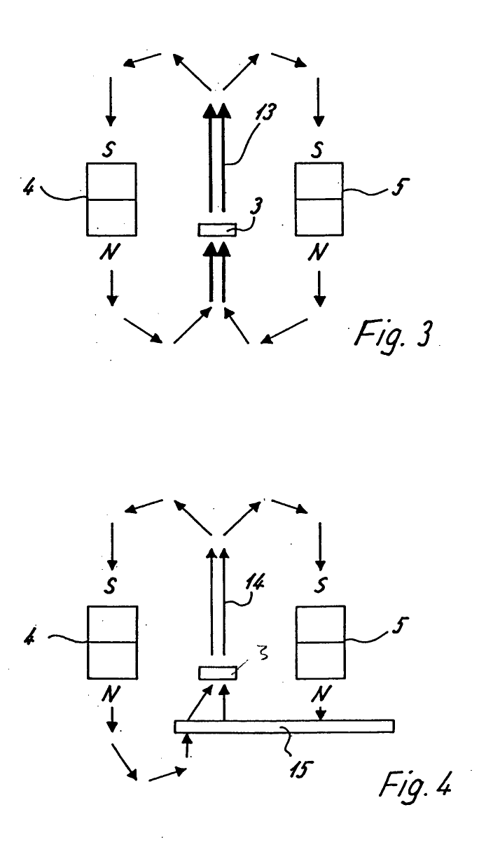

As illustrated in FIG. 3, the magnets 4 and 5 generate a homogenous magnetic field as a result of corresponding poles, the field lines of the magnetic field being schematically illustrated by arrows 13. The Hall sensor 3 is situated in the center between the magnets 4 and 5, the two magnetic fields overlapping there as the result of the magnets 4 and 5.

When a ferromagnetic generator 15 moves into one of the magnetic fields of the magnets 4 and 5 (FIG. 4), the homogenous magnetic field is disturbed. The deflection of the homogenous field lines results in generation of an analyzable signal amplitude at the Hall sensor 3. In this case, it is unimportant which of the illustrated lobar magnetic fields is deflected by the generator 15. However, the Hall sensor 3 can detect the deflection of the magnetic field.

If the direction of the ferromagnetic generator 15 is to be determined, for example, two or more sensor systems can be arranged adjacent to one another, so that the direction of the generator 15 and, if required, also the speed, can be measured.

As a result of the reduction of the field line concentration and of the magnetic flux density, an output voltage change occurs at the Hall sensor 3 which may, for example, be between 60 mV and 300 mV, depending on the working air gap between the sensor 3 and the ferromagnetic generator 15.

Since the sensitivity of the Hall sensor 3 is dependent on the temperature and the magnetic flux density of the magnets 4 and 5 decreases as the temperature rises, the system may be equipped with a temperature compensation. Since temperature compensation cannot be carried out by a simple measuring of the temperature, the temperature dependence can be reduced by an electronic analyzing system. For this purpose, an implemented algorithm can analyze the signal level change dU/dT. Thus signals changes of a certain amplitude are analyzed within a defined time period. Level changes in one direction indicate the detection of a generator, and signal edges in the opposite direction are recognized as a switch-off point.

If only a relatively small dU/dT is detected, the software triggers a temperature compensation mechanism. Level changes caused by a temperature drift, because of their variation in time, can be clearly differentiated from dynamic level changes caused by a moving generator. By this algorithm, the influences of a temperature drift and component tolerances are almost completely extracted.

Since the sensor 3 analyzes only signal edges, no calibration of the sensor 3 is required. The sensor 3 derives the air gap from the switch-on level difference and computes the required switch-off level therefrom. When generators are used which are guided parallel to the detection surface, this results in a pulse duty ratio which is almost independent of the air gap.

As a result, the illustrated sensor system has a small size and a high electromagnetic compatibility. Non-ferromagnetic metals do not impair the precision of the sensor system.

In the illustrated embodiment, only two magnets are arranged around the sensor. Naturally, it is also conceivable to position three, four or more magnets around the sensor, for example, in a ring-shaped manner.

Although the present disclosure has been described and illustrated in detail, it is to be clearly understood that this is done by way of illustration and example only and is not to be taken by way of limitation. The scope of the present disclosure is to be limited only by the terms of the appended claims.

1. A magnetic sensor system, particularly for transport systems, for detecting the presence of a ferromagnetic generator, the system comprising:
at least two adjacent magnets each creating a magnetic field;
a magnetic sensor in the magnetic fields of the magnets; and
the ferromagnetic generator can be moved in the magnetic fields relative to the magnetic sensor.

2. The sensor system according to claim 1, wherein the magnets are arranged so that the magnetic fields are two overlapping lobes.

3. The sensor system according to claim 1 wherein the sensor is a Hall sensor.

4. The sensor system according to claim 1, wherein the sensor only evaluates signal edges produced by the change in the magnetic fields.

5. The sensor system according to claim 1, wherein the sensor is a Hall sensor arranged in a center area of parallel magnetic field lines of the two magnets.

6. The sensor system according to claim 1, including temperature compensation of the detection of the generator.

7. The sensor system according to claim 1, wherein the sensor has a switching frequency above 5 kHz.

8. The sensor system according to claim 1, wherein a working air gap between the sensor and the generator is in a range between 1 and 14 mm.

9. The sensor system according to claim 1, including a microcontroller-controlled electronic analyzing system connected to the sensor.

10. The sensor system according to claim 1, wherein the system generates a detection signal when the generator is overlapped by at least 60% by the magnetic field.

11. The sensor system according to claim 1, wherein the sensor has a switching frequency above 10 kHz.
